(19) United States
(12) Patent Application Publication
(10) Pub. No.: US 2026/0271743 A1
(43) Pub. Date: Sep. 10, 2026

(54) SEMICONDUCTOR DEVICE

(71) Applicant: Mitsubishi Electric Corporation, Tokyo (JP)

(72) Inventors: Keitaro ICHIKAWA, Tokyo (JP); Takuya SAKAMOTO, Fukuoka (JP); Yuji SHIKASHO, Tokyo (JP); Sora HYODO, Tokyo (JP)

(73) Assignee: Mitsubishi Electric Corporation, Tokyo (JP)

(21) Appl. No.: 19/457,985

(22) Filed: Jan. 23, 2026

(30) Foreign Application Priority Data
Mar. 6, 2025 (JP) JP2025-035642

(51) Int. Cl. H10W 70/40; H10W 74/10

(52) U.S. Cl. CPC H10W 70/424; H10W 74/111

(57) ABSTRACT

A semiconductor device includes: a sealing body sealing a semiconductor element; main terminals electrically connected to the semiconductor element, led out from a surface of the sealing body, and arranged in a row; and a partition part extending to a right side from between the main terminals adjacent to each other of a right side surface to partition the main terminals adjacent to each other, wherein an unevenness is formed on a surface of the partition part. The semiconductor device further includes a partition part extending to a left side from between the signal terminals adjacent to each other of a left side surface to partition the main terminals adjacent to each other in a front-back direction, wherein an unevenness is formed on a surface of the partition part.

### BACKGROUND

### Technical Field

The present disclosure relates to a semiconductor device.

### Description of the Background Art

Japanese unexamined utility model application publication No. 6-23262 describes an electrical component in which a partition wall piece is formed between a plurality of terminals arranged in both end surfaces in a body of an integrated circuit surface-mounted to a wiring substrate. The partition wall piece is formed; thus, even when a cream solder formed by printing, for example, on a land of the wiring substrate is closely located between adjacent lands, the cream solder is partitioned by the partition wall piece. A creeping distance between terminals is ensured by providing an insulative partition such as the partition wall piece in Japanese unexamined utility model application publication No. 6-23262 to prevent short circuit between the terminals adjacent to each other.

### SUMMARY

In a resin-sealed intelligent power module in which a power semiconductor element and a control circuit controlling the power semiconductor element, for example, are packaged, it is desired to ensure the creeping distance between the terminals while suppressing increase of a device size in a plan view to increase a loading density of the module. Japanese unexamined utility model application publication No. 6-23262 can achieve increase of the creeping distance by increasing a thickness or a protrusion dimension of the partition wall piece, but has a problem that a device size increases in a plan view.

An object of the present disclosure is to provide a semiconductor device capable of ensuring a creeping distance between terminals while suppressing increase of a device size in a plan view.

A semiconductor device according to the present disclosure includes a sealing body, a plurality of terminals, and a partition part. The sealing body seals a semiconductor element. The plurality of terminals are electrically connected to the semiconductor element, led out from a surface of the sealing body, and arranged in a row. The partition part extends outside from between terminals adjacent to each other of the surface to partition the terminals adjacent to each other in a parallel direction in which the plurality of terminals are arranged. An unevenness is formed on a surface of the partition part.

A creeping distance between the terminals can be ensured while increase of a device size in a plan view is suppressed.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view of a semiconductor device according to an embodiment 1.

FIG. 2 is a side view of the semiconductor device according to the embodiment 1.

FIG. 3 is a plan view of a semiconductor device according to an embodiment 2.

FIG. 4 is a side view of the semiconductor device according to the embodiment 2.

### DESCRIPTION OF THE PREFERRED EMBODIMENTS

Although terms indicating a direction such as “upper” and “lower” are used in the description hereinafter, the direction such as “upper” and “lower” indicates a relative direction in a manufacturing device of a semiconductor device, thus does not limit a direction in using the manufacturing device of the semiconductor device.

### Embodiment 1

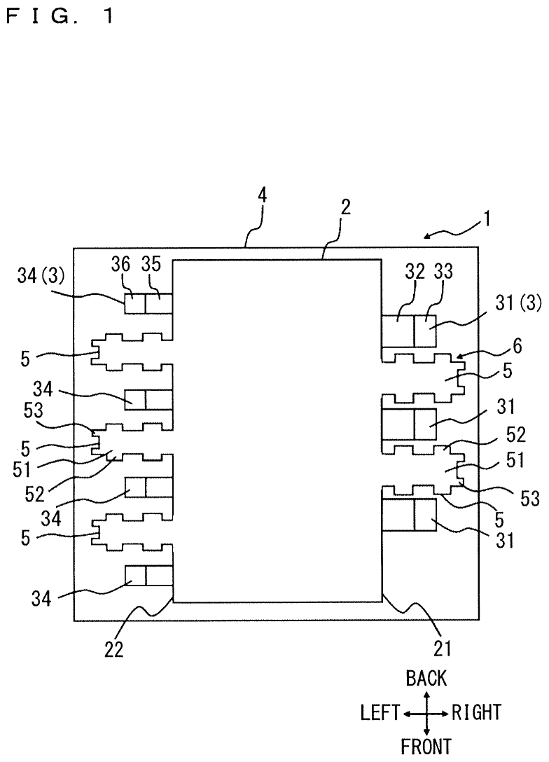

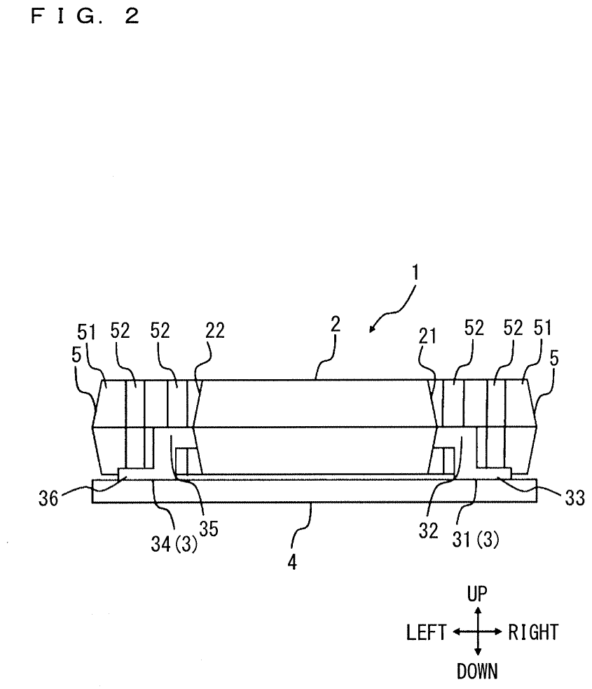

An embodiment 1 according to the present disclosure is described hereinafter using the diagrams. FIG. 1 is a plan view of a semiconductor device according to the embodiment 1. FIG. 2 is a side view of the semiconductor device according to the embodiment 1.

A semiconductor device 1 according to the embodiment 1 of the present disclosure is a resin-sealed intelligent power module in which a power part and a controller are mounted in the same package, and terminals 3 are provided on both sides of a resin sealing body 2 having electrical insulation properties.

The semiconductor device 1 includes the sealing body 2 sealing a semiconductor element (not shown), a terminal 3 electrically connected to the semiconductor element and exposed from the sealing body 2, and a circuit substrate 4 provided on a lower side of the sealing body 2 and connected to the terminal 3.

The semiconductor element includes a power semiconductor element and a control semiconductor element. It is sufficient that the power semiconductor element is a switching element or a diode. An insulated gate bipolar transistor (IGBT) or a metal oxide semiconductor field effect transistor (MOSFET), for example, may be used. A diode may be used for a reflux element. The control semiconductor element is an integrated circuit (an IC element) controlling the power semiconductor element. The number of semiconductor elements is not limited to one, but two or more semiconductor elements are also applicable. The semiconductor element is mounted to a metal frame made of copper, for example.

The sealing body 2 is a resin molding body manufactured by resin sealing by a transfer mold method and substantially having a rectangular parallelepiped shape elongated in a front-back direction. The sealing body 2 includes surfaces on each of upper, lower, right, left, front, and back sides, upper and lower surfaces are flat surfaces, and each side surface on the right, left, front, and back sides has a chevron shape in which a center part in an up-down direction is bent outside.

In a right side surface 21, a part of the metal frame is exposed from the sealing body 2, and main terminals 31 connected to the power semiconductor element are led out to be disposed in a row at regular intervals in the front-back direction. In the present embodiment, three main terminals 31 are provided. The main terminal 31 is a gull-wing type terminal, and includes a main terminal base end part 32 extending from the right side surface 21 to a right side and a main terminal distal end part 33 extending from a distal end of the main terminal base end part 32 to a lower side and further bending and extending to a right side. The main terminal distal end part 33 is electrically connected to the circuit substrate 4 by solder, for example.

A partition part 5 made up of the same resin as the sealing body 2 is continuously and integrally formed with the sealing body 2 between the main terminals 31 adjacent to each other in front and back of the right side surface 21. Since three main terminals 31 are provided in the present embodiment, two partition parts 5 are provided. In the meanwhile, the partition part 5 is not provided to an outer side in the front-back direction than the main terminals 31 on front-back both sides of the right side surface 21. Accordingly, there is a space on the outer side in the front-back direction than the main terminals 31 on front-back both sides, and a size of the semiconductor device 1 in a plan view can be suppressed by the space.

Each partition part 5 extends to an outer side than a distal end of the main terminal 31 in a protrusion direction, that is to say, extends closer to the right side than a distal end of the main terminal distal end part 33. Each partition part 5 substantially has a planar shape extending in a right-left direction, a thickness direction thereof coincides in the front-back direction, and a dimension thereof in the right-left direction is larger than that in the up-down direction. Each partition part 5 includes a partition part body 51 having a rectangular parallelepiped shape extending in the right-left direction, a facing convex part 52 provided to front-back both side surfaces of the partition part body 51 and facing the main terminal 31 in the front-back direction, and a distal end convex part 53 provided to a right side surface of the partition part 5, that is to say, a distal end surface thereof.

The facing convex parts 52 each have a rectangular parallelepiped shape elongated in the up-down direction, and are provided in a pair at an interval on right and left sides of each front-back side surface of the partition part 5. One facing convex part 52 or three or more facing convex parts 52 may be provided to each front-back side surface. Each facing convex part 52 is provided over whole of each front-back side surface in the up-down direction. The distal end convex parts 53 each have a rectangular parallelepiped shape elongated in the up-down direction, and are provided at intervals in front and back of the distal end surface of the partition part 5. One distal end convex part 53 or three or more distal end convex parts 53 may be provided to the distal end surface. As described above, an unevenness 6 is formed on the front-back both side surfaces and the distal end surface of the partition part 5. Accordingly, the unevenness 6 is formed in a portion of the surface of the partition part 5 facing the main terminal 31 and the distal end part of the partition part 5.

In a left side surface 22, a part of the metal frame is exposed from the sealing body 2, and signal terminals 34 connected to an IC element are led out to be disposed in a row at regular intervals in the front-back direction. In the present embodiment, four signal terminals 34 are provided. The signal terminal 34 is a gull-wing type terminal having a width smaller than the main terminal 31, and includes a signal terminal base end part 35 extending from the left side surface 22 to a left side and a signal terminal distal end part 36 extending from a distal end of the signal terminal base end part 35 to a lower side and further extending to a left side. The signal terminal distal end part 36 is electrically connected to the circuit substrate 4 by solder, for example.

The partition part 5 made up of the same resin as the sealing body 2 is continuously and integrally formed with the sealing body 2 between the signal terminals 34 adjacent to each other in front and back of the left side surface 22. Since four signal terminals 34 are provided in the present embodiment, three partition parts 5 are provided. In the meanwhile, the partition part 5 is not provided to the outer side in the front-back direction than the signal terminals 34 on front-back both sides of the left side surface 22. Accordingly, there is a space on the outer side in the front-back direction than the signal terminal 34 on an outermost side in the front-back direction, and a size of the semiconductor device 1 in a plan view can be suppressed by the space.

Each partition part 5 extends to an outer side than a distal end of the signal terminal 34 in a protrusion direction, that is to say, closer to a left side than a distal end of the signal terminal distal end part 36. Each partition part 5 substantially has a planar shape extending in the right-left direction, the thickness direction thereof coincides in the front-back direction, and the dimension thereof in the right-left direction is larger than that in the up-down direction. Each partition part 5 includes the partition part body 51 having the rectangular parallelepiped shape extending in the right-left direction, the facing convex part 52 provided to the front-back both side surfaces of the partition part body 51 and facing the signal terminal 34 in the front-back direction, and the distal end convex part 53 provided to the left side surface of the partition part 5, that is to say, the distal end surface thereof.

The facing convex parts 52 each have a rectangular parallelepiped shape elongated in the up-down direction, and are provided in a pair at an interval on right and left sides of each front-back side surface of the partition part 5. One facing convex part 52 or three or more facing convex parts 52 may be provided to each side surface in the front-back direction. Each facing convex part 52 is provided over whole of each front-back side surface in the up-down direction. The distal end convex parts 53 each have a rectangular parallelepiped shape elongated in the up-down direction, and are provided at intervals in front and back of the distal end surface of the partition part 5. One distal end convex part 53 or three or more distal end convex parts 53 may be provided to the distal end surface. As described above, the unevenness 6 is formed on the front-back side surfaces and the distal end surface of the partition part 5. Accordingly, the unevenness 6 is formed in a portion of the surface of the partition part 5 facing the signal terminal 34 and the distal end part of the partition part 5.

As described above, a creeping distance can be provided over a long distance by the unevenness 6 formed on the surface of the partition part 5 without using a dimension of the partition part 5 in the right-left direction. As a result, a creeping distance can be ensured while increase of a device size in a plan view can be suppressed. Since the unevenness 6 is formed on a portion facing the terminal 3 of the partition part 5 or the distal end surface, the creeping distance can be efficiently ensured. Furthermore, since the partition part 5 is formed to be longer than the terminal 3 in the right-left direction, a space distance of the adjacent terminals 3 can be provided.

### Embodiment 2

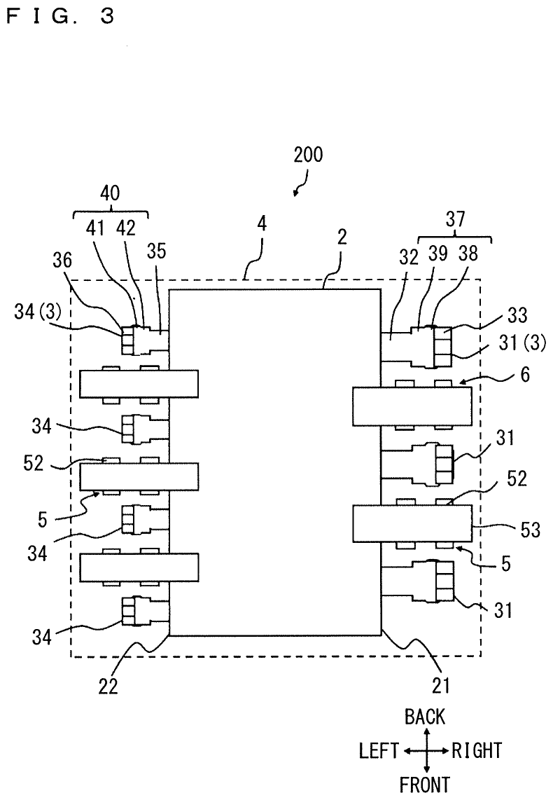

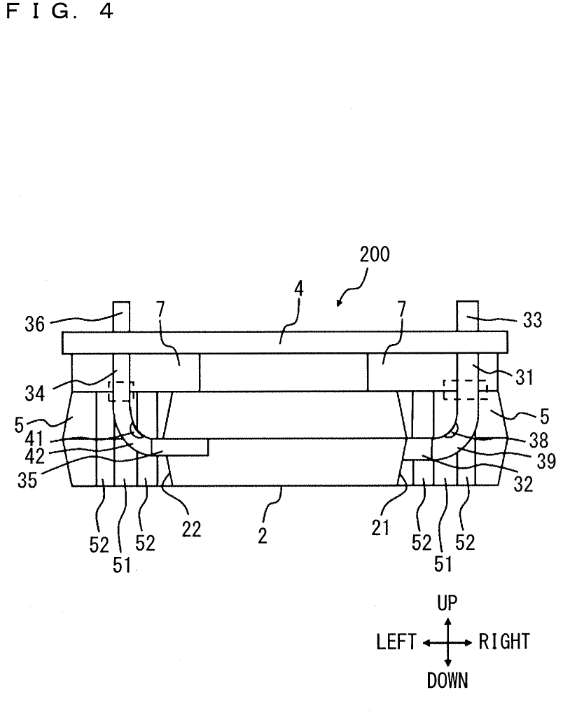

FIG. 3 is a plan view of a semiconductor device 200 according to an embodiment 2. FIG. 4 is a side view of the semiconductor device 200 according to the embodiment 2. In the semiconductor device 200 according to the embodiment 2, the same reference numerals are assigned to the same or similar configuration as those of the semiconductor device 1 according to the embodiment 1, and points different from those in the embodiment 1 are mainly described hereinafter.

The circuit substrate 4 is provided on an upper side of the sealing body 2, and the main terminal 31 and the signal terminal 34 pass through the circuit substrate 4. FIG. 3 illustrates an outline of the circuit substrate 4 by a broken line.

The main terminal 31 substantially has an L-like shape, and includes a main terminal base end part 32 extending from the right side surface 21 of the sealing body 2 to the right side and a main terminal distal end part 33 extending upward substantially with a width having a constant quadrangular prism-like shape. The main terminal distal end part 33 is inserted into a hole (not shown) formed in the circuit substrate 4, and is electrically connected to a circuit on the circuit substrate 4. The main terminal 31 includes an intermediate part 37 between the main terminal base end part 32 and the main terminal distal end part 33. The intermediate part 37 includes a first intermediate part 38 having a width larger than the main terminal base end part 32 and the main terminal distal end part 33 in the front-back direction and including a bending part bent upward and a second intermediate part 39 located between the first intermediate part 38 and the main terminal base end part 32 and having a width larger than the main terminal base end part 32 in the front-back direction and a width smaller than the first intermediate part 38 in the front-back direction. Accordingly, a shortest distance of the main terminals 31 adjacent to each other in the front-back direction is equal to a distance between the first intermediate parts 38 having a largest width in each main terminal 31. The bending part is expanded when the main terminal 31 is molded into a substantially the L-like shape, thus the first intermediate part 38 having the large width is formed.

The signal terminal 34 has a size smaller than the main terminal 31 as a whole, but substantially has a similar shape as the main terminal 31. The signal terminal 34 substantially has an L-like shape, and includes a signal terminal base end part 35 extending from the left side surface 22 of the sealing body 2 to the left side and a signal terminal distal end part 36 extending upward substantially with a width having a constant quadrangular prism-like shape. The signal terminal distal end part 36 is inserted into a hole (not shown) formed in the circuit substrate 4, and is electrically connected to the circuit on the circuit substrate 4. The signal terminal 34 includes an intermediate part 40 between the signal terminal base end part 35 and the signal terminal distal end part 36. The intermediate part 40 includes a first intermediate part 41 having a width larger than the signal terminal base end part 35 and the signal terminal distal end part 36 in the front-back direction and including a bending part bent upward and a second intermediate part 42 located between the first intermediate part 41 and the signal terminal base end part 35 and having a width larger than the signal terminal base end part 35 in the front-back direction and a width smaller than the first intermediate part 41 in the front-back direction. Accordingly, a shortest distance of the signal terminals 34 adjacent to each other in the front-back direction is equal to a distance between the first intermediate parts 41 having a largest width in each signal terminal 34. The bending part is expanded when the signal terminal 34 is molded into a substantially the L-like shape, thus the first intermediate part 41 having the large width is formed.

A spacer 7 is provided above each partition part 5. The spacer 7 is made up of an insulative member, and is provided between the sealing body 2 and the circuit substrate 4 and between the partition part 5 and the circuit substrate 4. Accordingly, a height position of the circuit substrate 4 is regulated. The spacer 7 extends from a position closer to an inner side than the right side surface 21 or the left side surface 22 of the sealing body 2 to the distal end of each partition part 5.

As described above, the shortest distance between the main terminals 31 adjacent to each other in the front-back direction is the distance between the first intermediate parts 38 having the largest width. However, when the partition part 5 is provided, the shortest distance between the main terminals 31 is the distance between the main terminal distal end parts 33. Specifically, the shortest distance between the main terminals 31 gets large in a gap between the partition part 5 and the spacer 7 shown by a frame of a broken line in FIG. 4. Accordingly, the space distance between the main terminals 31 adjacent to each other can get large by substantially an extension of the pair of first intermediate parts 38. In the similar manner, the space distance between the signal terminals 34 adjacent to each other also can get large by substantially an extension of the pair of first intermediate parts 41.

While the embodiments etc. have been described in detail, the above embodiments are not restrictive. Various modifications and replacements can be added to the above embodiments without departing from the scope of claims.

Although the semiconductor element is the power semiconductor element or the IC element in the embodiment described above, the configuration is not limited thereto.

Although the partition part 5 partitions the main terminals 31 adjacent to each other and the signal terminals 34 adjacent to each other in the embodiment described above, the configuration is not limited thereto. The partition part 5 may be provided only between the main terminals 31 adjacent to each other, for example.

Although the partition part 5 extends closer to the right and left outer sides than the main terminal 31 or the signal terminal 34 in the embodiment described above, the configuration is not limited thereto. The partition part 5 may have a protrusion dimension equal to or smaller than the main terminal 31 or the signal terminal 34.

Although the embodiment described above describes the switching element and the diode element formed of silicon, the switching element and the diode element may be formed by wide bandgap semiconductor having a larger bandgap than silicon. Examples of the wide bandgap semiconductor include silicon carbide, a gallium nitride series material, gallium oxide series material, or diamond. The switching element and the diode element formed of such wide bandgap semiconductor have high voltage resistance properties and a high allowable current density, thus are used under high voltage compared with Si. Although it is preferable that both the switching element and the diode element are formed of wide bandgap semiconductor, any one of the element may be formed of wide bandgap semiconductor.

Although the thickness (the dimension in the front-back dimension) of each of two partition parts 5 provided to the right side surface 21 of the sealing body 2 is the same as each other in the embodiment described above, the configuration is not limited thereto. The thickness thereof may be appropriately changed in accordance with the creeping distance to be ensured. The thickness of each of three partition parts 5 provided to the left side surface 22 of the sealing body 2 may be appropriately changed in the similar manner.

Although the partition part 5 substantially has a planar shape in the embodiment described above, the configuration is not limited thereto. The partition part 5 may have a shape capable of partitioning the terminals 3 adjacent to each other.

Although the unevenness 6 of the partition part 5 is formed of the facing convex part 52 and the distal end convex part 53 extending up and down and having a rectangular parallelepiped shape in the embodiment 1 described above, the configuration is not limited thereto. The unevenness 6 may have the other shape. For example, the convex part may be provided on the surface of the partition part body 51 to have a random spot-like shape.

Although the unevenness 6 is formed also on the partition part 5 on the side of the signal terminal 34 in the embodiment 1 described above, the configuration is not limited thereto. The unevenness 6 may not be provided to the partition part 5 on the side of the signal terminal 34.

The aspects of the present disclosure are collectively described hereinafter as appendixes.

### (Appendix 1)

A semiconductor device, comprising:
a sealing body sealing a semiconductor element;
a plurality of terminals electrically connected to the semiconductor element, led out from a surface of the sealing body, and arranged in a row; and
a partition part extending outside from between terminals adjacent to each other of the surface to partition the terminals adjacent to each other in a parallel direction in which the plurality of terminals are arranged, wherein
an unevenness is formed on a surface of the partition part.

### (Appendix 2)

The semiconductor device according to Appendix 1, wherein
the unevenness is formed on a portion of the surface of the partition part, the portion facing the terminals in the parallel direction.

### (Appendix 3)

The semiconductor device according to Appendix 1 or 2, wherein
the unevenness is formed on a distal end part of the partition part.

### (Appendix 4)

The semiconductor device according to any one of Appendixes 1 to 3, wherein
the partition part extends to an outer side than the terminals.

### (Appendix 5)

The semiconductor device according to any one of claims 1 to 4, wherein
each of the terminals extends outside and is bent upward in a midway portion and includes a base end part protruding from the sealing body, a distal end part as a part of a distal end extending from the base end part, and an intermediate part between the distal end part and the base end part,
the intermediate part includes a first intermediate part having a width larger in the parallel direction than the base end part and the distal end part and including a bending part bent upward and a second intermediate part located between the first intermediate part and the base end part, having a width larger than the base end part in the parallel direction, and having a width smaller than the first intermediate part in the parallel direction.

### (Appendix 6)

The semiconductor device according to any one of Appendixes 1 to 5, wherein
the terminals include main terminals connected to a power semiconductor element, and
the partition part partitions the main terminals adjacent to each other.

### (Appendix 7)

The semiconductor device according to Appendix 6, wherein
the terminals include signal terminals connected to an IC element,
the signal terminals are arranged in a row on a surface on a side opposite to a surface on which the main terminals are arranged, and
the partition part partitions the signal terminals adjacent to each other.

While the disclosure has been shown and described in detail, the foregoing description is in all aspects illustrative and not restrictive. It is therefore understood that numerous modifications and variations can be devised.

What is claimed is:

1. A semiconductor device, comprising:
a sealing body sealing a semiconductor element;
a plurality of terminals electrically connected to the semiconductor element, led out from a surface of the sealing body, and arranged in a row; and
a partition part extending outside from between terminals adjacent to each other of the surface to partition the terminals adjacent to each other in a parallel direction in which the plurality of terminals are arranged, wherein
an unevenness is formed on a surface of the partition part.

2. The semiconductor device according to claim 1, wherein
the unevenness is formed on a portion of the surface of the partition part, the portion facing the terminals in the parallel direction.

3. The semiconductor device according to claim 2, wherein
the unevenness is formed on a distal end part of the partition part.

4. The semiconductor device according to claim 1, wherein
the partition part extends to an outer side than the terminals.

5. The semiconductor device according to claim 1, wherein
each of the terminals extends outside and is bent upward in a midway portion and includes a base end part protruding from the sealing body, a distal end part as a part of a distal end extending from the base end part, and an intermediate part between the distal end part and the base end part, and
the intermediate part includes a first intermediate part having a width larger in the parallel direction than the base end part and the distal end part and including a bending part bent upward and a second intermediate part located between the first intermediate part and the base end part, having a width larger than the base end part in the parallel direction, and having a width smaller than the first intermediate part in the parallel direction.

6. The semiconductor device according to claim 1, wherein
the terminals include main terminals connected to a power semiconductor element, and
the partition part partitions the main terminals adjacent to each other.

7. The semiconductor device according to claim 6, wherein
the terminals include signal terminals connected to an IC element,
the signal terminals are arranged in a row on a surface on a side opposite to a surface on which the main terminals are arranged, and
the partition part partitions the signal terminals adjacent to each other.
